(19) United States
(12) Patent Application Publication
(10) Pub. No.: US 2021/0408277 A1
(43) Pub. Date: Dec. 30, 2021

(54) Transistor Device Structure

(71) Applicant: Shanghai Huali Integrated Circuit Corporation, Shanghai (CN)

(72) Inventor: Wenyin Weng, Shanghai (CN)

(73) Assignee: Shanghai Huali Integrated Circuit Corporation, Shanghai (CN)

(21) Appl. No.: 17/095,981

(22) Filed: Nov. 12, 2020

(30) Foreign Application Priority Data
Jun. 30, 2020 (CN) 202010611970.0

(51) Int. Cl. H01L 29/78; H01L 27/088; H01L 29/417; H01L 29/66; H01L 29/06

(52) U.S. Cl. CPC H01L 29/785; H01L 27/0886; H01L 2029/7858; H01L 29/66795; H01L 29/0649; H01L 29/41791

(57) ABSTRACT

A transistor device comprising a core device and an input/output device, a field oxide layer isolates an active region of a core device region from an active region of an input/output device region on a semiconductor substrate, a gate-all-around structure is formed in the active region of the core device region, and a fin gate structure is formed in the active region of the input/output device region, thereby improving the short channel effect of the core device. In addition, the thickness of a gate dielectric layer of the fin gate structure of the input/output device is not affected by a gap between channel wires of the gate-all-around structure, such that the on-current and off-current performance of the input/output device is not affected when the short channel effect of the core device is improved.

### CROSS-REFERENCES TO RELATED APPLICATIONS

This application claims priority to Chinese Patent Application No. 202010611970.0, filed on Jun. 30, 2020, and entitled “Transistor Device Structure”, the disclosure of which is incorporated herein by reference in entirety.

### TECHNICAL FIELD

The present application relates to the field of semiconductor integrated circuit s, in particular to a transistor device structure.

### BACKGROUND

In the existing advanced logic chips, there usually exist an n-type field-effect transistor (FET), i.e., nFET, and a p-type field-effect transistor, i.e., pFET, and there usually exist nFET and pFET serving as core devices and nFET and pFET serving as input/output (I/O) devices. Referring to FIG. 1, which is a structural schematic diagram of an existing transistor device, it can be seen from FIG. 1 that, a field oxide layer 101 is formed in a semiconductor substrate 100, and the field oxide layer 101 is usually formed by means of a shallow trench isolation (STI) process. The field oxide layer 101 isolates active regions from each other, the active regions include an active region of a core device region that core devices are formed in and an active region of an input/output device region that input/output devices are formed in. As can be seen from FIG. 1, a gate structure 131 of a core nFET and a gate structure 141 of a core pFET are formed in the active region of the core device region, and a gate structure 111 of an input/output nFET and a gate structure 121 of an input/output pFET are formed in the active region of the input/output device region. Each of the gate structures includes a polysilicon gate 112, a hard mask layer formed by stacking a nitride layer 113 and an oxide layer 114, and a side wall 115. A channel region is formed on the surface of the semiconductor substrate 100 of a region covered by the polysilicon gate 112, as can be seen from FIG. 1, the channel length of the input/output device is greater than the channel length of the core device.

With the continuous development of semiconductor technologies, the planar device as shown in FIG. 1 can no longer meet the demand for high-performance devices of users. In this case, the fin field-effect transistor (FinFET) comes into being, which is a three-dimensional device, and compared with planar transistors, the fin field-effect transistor has a three-dimensional channel structure, thus having better on-current and off-current characteristics and being able to improve the short channel effect (SCE). The FinFET generally includes a fin, which is formed by a nanostrip or nanosheet formed on a semiconductor substrate. The fins on the same semiconductor substrate are arranged in parallel, and a dielectric layer is isolated between the fins. A gate structure covers the top surface and side surfaces of the fin of a partial length, and the surface of the fin covered by the gate structure is used to form a channel, that is, channels are provided on the top surface and two side surfaces of the fin. Generally, the gate structure includes a gate dielectric layer and a gate conductive material layer which are stacked up. A source region and a drain region are formed in the fins on two sides of the gate structure.

With the development of semiconductor technologies, the device size decreases continuously. At the technology node below 5 nm, the fin field-effect transistor adopts a nanowire or nanosheet gate-all-around (GAA) structure, which can further improve the short channel effect. Referring to FIG. 2, which is a schematic diagram of a gate-all-around structure, as can be seen from FIG. 2, the gate-all-around structure includes a wire 144 formed on a fin 110 on a semiconductor substrate. A channel region of the semiconductor device is formed in the wire 144, and a gate dielectric layer 122 is formed on the peripheral of the wire 144. A work function layer 133 is formed on the peripheral of the gate dielectric layer 122 and between the gate dielectric layer 122 and the semiconductor substrate. The GAA structure can effectively improve the short channel effect of the device.

As can be seen from FIG. 2, there are two wires 144 vertically stacked on the fin 110, and there is a gap between the two wires 144. Referring to FIG. 2, assuming that the diameter d1 of the wire 144 is 10 nm and the gap d2 between the two wires 144 is 20 nm, then the thickness of the gate dielectric layer 122 is necessarily less than 5 nm; if the thickness of the gate dielectric layer 122 is greater than 5 nm, the gate dielectric layers 122 overlap, as can be seen from FIG. 3, which is a schematic diagram of the gate-all-around structure in which a gate dielectric layer is relatively thick, in which case the on-current/off-current (Ion/Ioff) characteristics of the device are affected, and the size of the wire 144 needs to be sacrificed to increase the thickness of the gate dielectric layer 122. Therefore, for input/output (I/O) devices, the GAA structure may affect the device performance thereof.

### BRIEF SUMMARY OF THE DISCLOSURE

According to some embodiments in this application, a transistor device structure provided in the present application comprises: a semiconductor substrate, wherein a field oxide layer is formed in the semiconductor substrate, the field oxide layer isolates active regions from each other, the active regions include an active region of a core device region that core devices are formed in and an active region of an input/output device region that input/output devices are formed in; a plurality of fins including fins in the input/output device region and fins in the core device region, wherein the plurality of fins are strip structures formed by performing photolithography process and etching process to an epitaxial layer on the semiconductor substrate, all of the fins are arranged in parallel, the bottoms of the plurality of fins are isolated from each other by means of a first insulation layer formed on the semiconductor substrate, a portion of the fin in the core device region above the first insulation layer includes a wire composed of a semiconductor material, the periphery of a partial length of the wire is coated by a first gate dielectric layer, a first work function layer is formed on the peripheral of the first gate dielectric layer and between the first gate dielectric layer and the first insulation layer, a second gate dielectric layer is formed on a portion of the top surface and side surface of the fins in the input/output device region above the first insulation layer, and a second work function layer is formed on the surface of the second gate dielectric layer; and a metal gate covering the top surface and side surface of the first work function layer and the second work function layer and filling a gap between the first work function layers, a gap between the second work function layers, and a gap between the first work function layer and the second work function layer, wherein a portion of the fin in the input/output device region covered by the metal gate forms a channel region of an input/output device, and a portion of the wire in the core device region covered by the metal gate forms a channel region of a core device.

### BRIEF DESCRIPTION OF THE DRAWINGS

FIG. 1 is a structural schematic diagram of an existing transistor device;

FIG. 2 is a schematic diagram of a gate-all-around structure;

FIG. 3 is a schematic diagram of the gate-all-around structure in which a gate dielectric layer is relatively thick;

FIG. 4 is a planar schematic diagram of a transistor device according to an embodiment of the present application; and

FIG. 5 is a sectional diagram of the transistor device according to an embodiment of the present application.

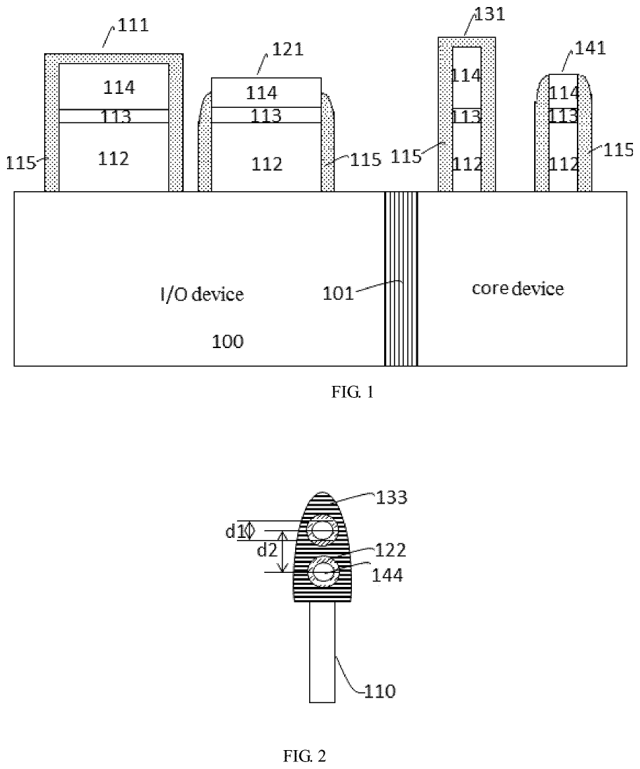

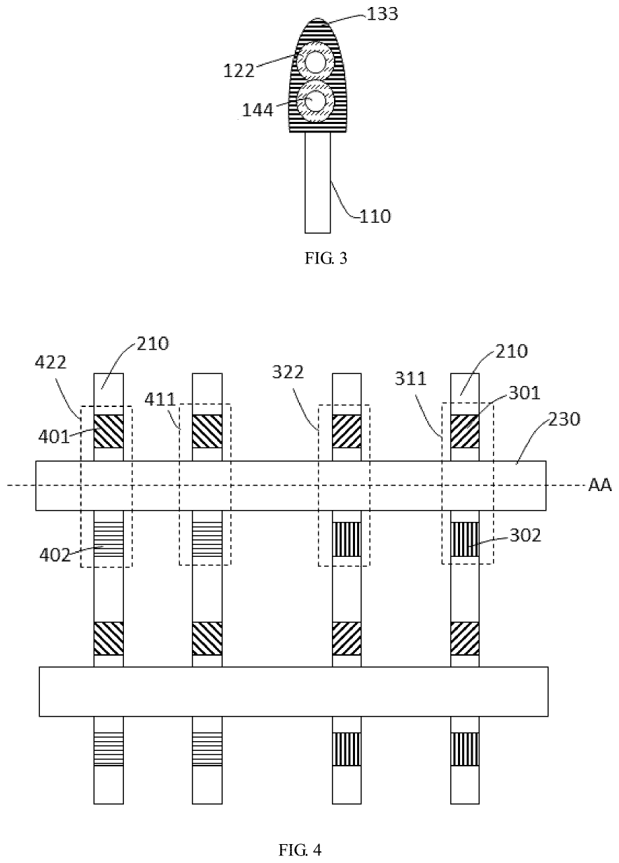

Reference signs of main components in the drawings are explained as follows:

200, semiconductor substrate; 201, field oxide layer; 210, fin; 220, first insulation layer; 211, first oxide layer wire body; 222, first gate dielectric layer; 233, first work function layer; 322, second gate dielectric layer; 333, second work function layer; 230, metal gate.

### DETAILED DESCRIPTION OF THE DISCLOSURE

The technical solution of the present application will be clearly and completely described below with reference to the drawings. Obviously, the described embodiments are part of the embodiments of the present application, instead of all of them. Based on the embodiments in the present application, all other embodiments obtained by one skilled in the art without contributing any inventive labor shall fall into the protection scope of the present application.

One embodiment of the present application provides a transistor device structure including: a semiconductor substrate, wherein a field oxide layer is formed in the semiconductor substrate, the field oxide layer isolates active regions from each other, the active regions include an active region of a core device region that core devices are formed in and an active region of an input/output device region that input/output devices are formed in; a plurality of fins including fins in the input/output device region and fins in the core device region, wherein the plurality of fins are strip structures formed by performing photolithography process and etching process to an epitaxial layer on the semiconductor substrate, all of the fins are arranged in parallel, the bottoms of the plurality of fins are isolated from each other by means of a first insulation layer formed on the semiconductor substrate, a portion of the fin in the core device region above the first insulation layer includes a wire composed of a semiconductor material, the periphery of a partial length of the wire is coated by a first gate dielectric layer, a first work function layer is formed on the peripheral of the first gate dielectric layer and between the first gate dielectric layer and the first insulation layer, a second gate dielectric layer is formed on a portion of the top surface and side surface of the fins in the input/output device region above the first insulation layer, and a second work function layer is formed on the surface of the second gate dielectric layer; and a metal gate covering the top surface and side surface of the first work function layer and the second work function layer and filling a gap between the first work function layers, a gap between the second work function layers, and a gap between the first work function layer and the second work function layer, wherein a portion of the fin in the input/output device region covered by the metal gate forms a channel region of an input/output device, and a portion of the wire in the core device region covered by the metal gate forms a channel region of a core device.

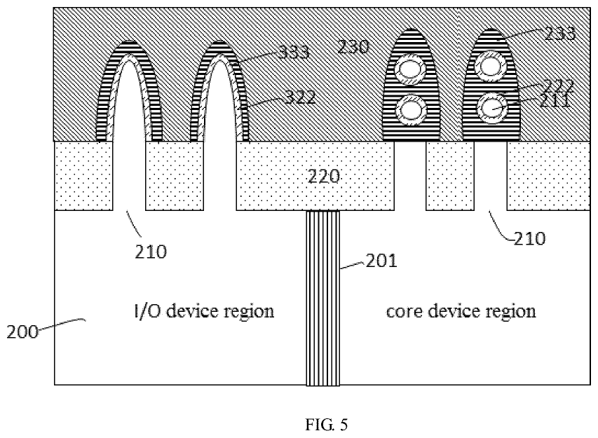

Referring to FIGS. 4 and 5, it can be seen that FIG. 4 is a planar schematic diagram of a transistor device according to an embodiment of the present application, FIG. 5 is a sectional diagram of the transistor device according to an embodiment of the present application, and FIG. 5 is a diagram of a section obtained by cutting the transistor device along the dashed line AA in FIG. 5. The transistor device structure of the present application includes:

a semiconductor substrate 200, wherein a field oxide layer 200 is formed in the semiconductor substrate 200, the field oxide layer 201 isolates active regions from each other, the active regions include an active region of a core device region that core devices are formed in and an active region of an input/output device region that input/output devices are formed in;

a plurality of fins 210 including fins in the input/output device region and fins in the core device region, wherein the plurality of fins 210 are strip structures formed by performing photolithography process and etching process to an epitaxial layer on the semiconductor substrate 200, all of the fins 210 are arranged in parallel, the bottoms of the plurality of fins 210 are isolated from each other by means of a first insulation layer 220 formed on the semiconductor substrate 200, a portion of the fin 210 in the core device region above the first insulation layer 220 includes a wire 211 composed of a semiconductor material, the periphery of a partial length of the wire 211 is coated by a first gate dielectric layer 222, a first work function layer 233 is formed on the peripheral of the first gate dielectric layer 222 and between the first gate dielectric layer 222 and the first insulation layer 220, a second gate dielectric layer 322 is formed on a portion of the top surface and side surface of the fins 210 in the input/output device region above the first insulation layer 220, and a second work function layer 333 is formed on the surface of the second gate dielectric layer 322; and

a metal gate 230 covering the top surface and side surface of the first work function layer 233 and the second work function layer 333 and filling a gap between the first work function layers 233, a gap between the second work function layers 333, and a gap between the first work function layer 233 and the second work function layer 333, wherein a portion of the fin 210 in the input/output device region covered by the metal gate 230 forms a channel region of an input/output device, and a portion of the wire 211 in the core device region covered by the metal gate 230 forms a channel region of a core device.

In an embodiment, the semiconductor substrate 200 is a silicon substrate. In an embodiment, the field oxide layer 201 is generally formed by means of a shallow trench isolation process.

In an embodiment, the portion of the fin 210 in the input/output device region above the first insulation layer 220 includes at least one stacking layer of silicon and silicon germanium epitaxial layers.

In an embodiment, there are two vertically stacked wires 211, the peripheries of a partial length of the two wires 211 are coated by the first gate dielectric layer 222, the first work function layer 233 is formed on the periphery of the first dielectric layer 222, between the first gate dielectric layers 222, and between the first gate dielectric layer 222 and the first insulation layer 220, and the portion of the fin 210 in the input/output device region above the first insulation layer 220 includes two stacking layers of silicon and silicon germanium epitaxial layers. In the present application, there may be more than two vertically stacked wires 211, which are not limited in the present application.

In an embodiment of the present application, the semiconductor material of the wire 211 is silicon. In an embodiment, a sectional structure of the wire 211 is a circle, or a polygon such as a square, a rectangle, or a Σ-shape.

In an embodiment, the first gate dielectric layer 222 and the second gate dielectric layer 322 include a high dielectric constant layer, and the material of the high dielectric constant layer includes silicon dioxide, silicon nitride, aluminum oxide, tantalum pentoxide, yttrium oxide, hafnium silicate, hafnium dioxide, lanthanum oxide, zirconium dioxide, strontium titanate, and zirconium silicate.

In an embodiment, the first insulation layer 220 is an oxide layer.

More specifically, in an embodiment of the present application, a source 301 is formed on one side of the channel region of the core device on the fin in the core device region and a drain 302 is formed on the other side of the channel region of the core device on the fin in the core device region, to form a gate-all-around structure field-effect transistor serving as a core device; and a source 401 is formed on one side of the channel region of the input/output device on the fin in the input/output device region and a drain 402 is formed on the other side of the channel region of the input/output device on the fin in the input/output device region, to form a fin field-effect transistor serving as an input/output device.

In an embodiment, the gate-all-around structure field-effect transistors serving as core devices include an n-type gate-all-around structure field-effect transistor 311 and a p-type gate-all-around structure field-effect transistor 322; and the fin field-effect transistors serving as input/output devices include an n-type fin field-effect transistor 411 and a p-type fin field-effect transistor 422. In an embodiment of the present application, the source and the drain both are embedded structures. The source and drain of the n-type fin field-effect transistor 411 and the n-type gate-all-around structure field-effect transistor 311 are composed of a first embedded epitaxial layer, and the material of the first embedded epitaxial layer is SixPy, SimCn, or SioCpPq, wherein subscripts x, y, m, n, o, p, and q respectively represent the number of corresponding atoms in a material molecule. The source and drain of the p-type fin field-effect transistor 422 and the p-type gate-all-around structure field-effect transistor 322 are composed of a second embedded epitaxial layer, and the material of the second embedded epitaxial layer is SihGei, wherein subscripts h and i respectively represent the number of corresponding atoms in a material molecule.

In addition, the transistor device of the present application is a device of a technology node below 5 nm.

As described above, in a transistor device including core devices and input/output devices, a field oxide layer isolates an active region of a core device region from an active region of an input/output device region on a semiconductor substrate, a gate-all-around structure is formed in the active region of the core device region, and a fin gate structure is formed in the active region of the input/output device region, thereby improving the short channel effect of the core device. In addition, the thickness of a gate dielectric layer of the fin gate structure of the input/output device is not affected by a gap between channel wires of the gate-all-around structure, such that the on-current and off-current performance of the input/output device is not affected when the short channel effect of the core device is improved.

Finally, it should be noted that the above embodiments are only used for describing the technical solutions of the present application, instead of limiting the technical solutions. Although the present application is described in detail with reference to the above embodiments, it should be understood by one skilled in the art that the technical solutions recorded in the above embodiments may still be modified, or some or all of the technical features may be replaced equivalently. These modifications or replacements do not make the essence of the corresponding technical solution deviate from the scope of the technical solutions of the embodiments of the present application.

What is claimed is:

1. A transistor device structure, comprising:
a semiconductor substrate, wherein a field oxide layer is formed in the semiconductor substrate, the field oxide layer isolates active regions from each other, the active regions include an active region of a core device region that core devices are formed in and an active region of an input/output device region that input/output devices are formed in;
a plurality of fins including fins in the input/output device region and fins in the core device region, wherein the plurality of fins are strip structures formed by performing photolithography process and etching process to an epitaxial layer on the semiconductor substrate, all of the fins are arranged in parallel, the bottoms of the plurality of fins are isolated from each other by means of a first insulation layer formed on the semiconductor substrate, a portion of the fin in the core device region above the first insulation layer includes a wire composed of a semiconductor material, the periphery of a partial length of the wire is coated by a first gate dielectric layer, a first work function layer is formed on the peripheral of the first gate dielectric layer and between the first gate dielectric layer and the first insulation layer, a second gate dielectric layer is formed on a portion of the top surface and side surface of the fins in the input/output device region above the first insulation layer, and a second work function layer is formed on the surface of the second gate dielectric layer; and
a metal gate covering the top surface and side surface of the first work function layer and the second work function layer and filling a gap between the first work function layers, a gap between the second work function layers, and a gap between the first work function layer and the second work function layer, wherein a portion of the fin in the input/output device region covered by the metal gate forms a channel region of an input/output device, and a portion of the wire in the core device region covered by the metal gate forms a channel region of a core device.

2. The transistor device structure according to claim 1, wherein the portion of the fin in the input/output device region above the first insulation layer comprises at least one stacking layer of silicon and silicon germanium epitaxial layers.

3. The transistor device structure according to claim 1, wherein there are two vertically stacked wires, the peripheries of a partial length of the two wires are coated by the first gate dielectric layer, the first work function layer is formed on the periphery of the first dielectric layer, between the first gate dielectric layers, and between the first gate dielectric layer and the first insulation layer, and the portion of the fin in the input/output device region above the first insulation layer comprises two stacking layers of silicon and silicon germanium epitaxial layers.

4. The transistor device structure according to claim 1, wherein the semiconductor substrate is a silicon substrate, and the semiconductor material of the wire is silicon.

5. The transistor device structure according to claim 1, wherein the first gate dielectric layer and the second gate dielectric layer comprise a high dielectric constant layer.

6. The transistor device structure according to claim 1, wherein the first insulation layer is an oxide layer.

7. The transistor device structure according to claim 1, wherein a source is formed on one side of the channel region of the core device on the fin in the core device region and a drain is formed on the other side of the channel region of the core device on the fin in the core device region, to form an n-type gate-all-around structure field-effect transistor and a p-type gate-all-around structure field-effect transistor; and a source is formed on one side of the channel region of the input/output device on the fin in the input/output device region and a drain is formed on the other side of the channel region of the input/output device on the fin in the input/output device region, to form an n-type fin field-effect transistor and a p-type fin field-effect transistor.

8. The transistor device structure according to claim 7, wherein the source and the drain both are embedded structures, the source and drain of the n-type fin field-effect transistor and the n-type gate-all-around structure field-effect transistor are composed of a first embedded epitaxial layer, and the source and drain of the p-type fin field-effect transistor and the p-type gate-all-around structure field-effect transistor are composed of a second embedded epitaxial layer.

9. The transistor device structure according to claim 1, wherein a sectional structure of the wire is a circle or a polygon.

10. The transistor device structure according to claim 1, wherein the transistor device is a device of a technology node below 5 nm.
